(19) United States
(12) Patent Application Publication
(10) Pub. No.: US 2007/0287280 A1
(43) Pub. Date: Dec. 13, 2007

(54) Composition for removing a photoresist and method of forming a bump electrode

(75) Inventors: Dong-Min Kang, Uiwang-si (KR); Young-Sam Lim, Bucheon-si (KR); Gi-Jung Kim, Yongin-si (KR); Young-Nam Kim, Suwon-si (KR); Yun-Deok Kang, Suwon-si (KR); Ji-Sung Lee, Seongnam-si (KR); Ki-Hyeon Kim, Seoul (KR); Kyoung-Jin Choi, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/808,584

(22) Filed: Jun. 12, 2007

(30) Foreign Application Priority Data
Jun. 12, 2006 (KR) 10-2006-0052659

(51) Int. Cl. H01L 21/44

(52) U.S. Cl. 438/613; 257/E21.508

(57) ABSTRACT

A composition for removing a photoresist and a method of forming a bump electrode using the composition are provided. The composition includes an amine compound having a hydroxyl group, a polar organic solvent having a heteroatom, an alkylammonium hydroxide and water. The method of forming the bump electrode includes forming a conductive pattern on a substrate, forming a passivation layer on the substrate, the passivation layer having a first opening that partially exposes the conductive pattern, forming a photoresist pattern on the passivation layer, the photoresist pattern having a second opening that exposes the first opening forming a bump electrode that fills the first opening and the second opening, and removing the photoresist pattern from the substrate using a composition including an amine compound having a hydroxyl group, a polar organic solvent having a heteroatom, an alkylammonium hydroxide and water.

### PRIORITY STATEMENT

This application claims the benefit of priority under 35 U.S.C. § 119 to Korean Patent Application No. 10-2006-0052659, filed on Jun. 12, 2006, the contents of which are herein incorporated by reference in its entirety.

### BACKGROUND

1. Field

Example embodiments relate to a composition for removing a photoresist and a method of forming a bump electrode using the composition. Other example embodiments relate to a composition for more effectively removing a photoresist that may be used in a process for forming a bump electrode and a method of forming a bump electrode using the composition.

2. Description of the Related Art

To mount a semiconductor chip on a printed circuit board of an electronic device, the semiconductor chip generally includes a bump electrode as a connection element. The bump electrode may protrude from the semiconductor chip by a height greater than several tens of micrometers (e.g., >10 μm). A bump electrode having more precise dimensions and structure has been developed in order to satisfy the demand for a more highly integrated semiconductor chip.

The bump electrode may be formed on a semiconductor device by processes known in the art (e.g., electroplating, vacuum evaporation, stirring using a wire bonding, etc.). Electroplating, which is relatively simple and economical, is widely used.

In an electroplating process, a passivation layer pattern may be formed on a substrate having a metal wiring formed thereon. The passivation layer pattern may be formed such that a bump contact region of the metal wiring is exposed. A seed layer or a metal base layer may be formed in the bump contact region to electroplate a metal for the bump electrode. A photoresist pattern may be formed on the substrate such that the bump contact region is exposed. The bump contact region may be filled with the metal for the bump electrode. The photoresist pattern may be removed.

The photoresist pattern is formed substantially thicker than a desired thickness of the bump electrode. A thick photoresist, which includes a photoresist film having a thickness greater than about 5 μm, may be used to form the photoresist pattern. The thick photoresist may have a higher adhesive strength relative to the substrate, a higher plating solution resistance and/or a higher wettability against the plating solution. After performing the electroplating process, the photoresist may be removed from the substrate.

When the photoresist pattern having a thickness of several tens or micrometers is formed using the thick photoresist, then a bottom portion of the photoresist pattern may not be exposed to light in an exposure process. When the photoresist pattern is removed by a subsequent ashing process, the photoresist pattern may be damaged by plasma used in the ashing process. In a subsequent stripping process, some of the photoresist pattern may remain between the bump electrodes forming a residue of a thread scrap, possibly resulting in a failure of the semiconductor device.

In the stripping process, a composition used as a stripper dissolves the photoresist pattern and detaches the photoresist pattern from the substrate. When the stripper fails to dissolve or detach the photoresist pattern, then the photoresist pattern may remain on the substrate. When the stripper cannot be mixed with water, then the photoresist pattern may remain on the substrate. Most organic strippers are suitable for removing a polymer, but not a photoresist. As such, when the stripper is used to remove the photoresist (forming the bump electrode), then the photoresist may not be stripped or may be recoated on the substrate. A stripping process is performed twice using two types of strippers lengthening the processing time.

A thinner composition may also be used for removing the photoresist. The thinner composition may process a semiconductor substrate using one sheet. When the thinner composition is used for processing a plurality of substrates simultaneously, the photoresist pattern may remain on the substrate, reducing the efficiency of the process.

According to the conventional art, monoethanolamine may be used as a solution for stripping a photoresist. The conventional art discloses a composition including monoethanolamine to strip the photoresist. Although the composition is suitable for stripping a thin photoresist film having a thickness of about several microns, the composition may not be suitable for stripping a thicker photoresist film.

The conventional art also acknowledges a composition for removing photoresist that may be used for forming a bump electrode. The composition includes about 13 percent by weight (% wt.) to about 37% wt. of monoethanolamine and about 63% wt. to about 87% wt. of dimethylacetamide. However, the conventional composition may not effectively remove a novolac-based photoresist. The composition may require a higher processing temperature and/or a longer processing time for removing the photoresist. For example, the composition may be applied to remove the photoresist at a temperature of at least about 60° C. for at least thirty minutes. When the process of removing photoresist is carried out at a higher temperature for a longer period of time, then the passivation layer (which is provided during the formation of the bump electrode and formed using polyimide) may be damaged by the composition, generating defects in the semiconductor device.

### SUMMARY

Example embodiments relate to a composition that may more effectively remove a photoresist used for forming a bump electrode at a lower temperature within a shorter time and/or may reduce the likelihood of damaging a polyimide film.

Example embodiments relate to a method of forming a bump electrode using the above-mentioned composition.

According to example embodiments, a composition for removing photoresist includes about 22% wt. to about 46% wt. of an amine compound having a hydroxyl group, about 52% wt. to about 75% wt. of a polar organic solvent having a heteroatom, about 0.3% wt. to about 2% wt. of an alkylammonium hydroxide and a remainder of water. Examples of the amine compound may include hydroxylamine, monoethanolamine or a combination thereof. Examples of the polar organic solvent may include N-methyl-2-pyrrolidinone, dimethylacetamide, dimethyl sulfoxide or the like. An example of the alkylammonium hydroxide may include a tetraalkylammonium hydroxide having C₁-C₄ alkyl groups.

According to example embodiments, there is provided a method of forming a bump electrode. In the method, a conductive pattern is formed on a substrate. A passivation layer having a first opening is formed on the substrate. The first opening partially exposes the conductive pattern. A photoresist pattern having a second opening may be formed on the passivation layer. The second opening exposes the first opening. After a bump electrode is formed filling the first opening and the second opening, the photoresist pattern may be removed from the substrate using a composition that includes an amine compound having a hydroxyl group, a polar organic solvent having a heteroatom, an alkylammonium hydroxide and water.

According to example embodiments, the composition may more effectively remove a novolac-based photoresist used to form a bump electrode at a relatively lower temperature within a relatively shorter time. The composition may prevent (or reduce) damage to the passivation layer that is formed using polyimide.

### BRIEF DESCRIPTION OF THE DRAWINGS

Example embodiments will be more clearly understood from the following detailed description taken in conjunction with the accompanying drawings. FIGS. 1 through 10 represent non-limiting, example embodiments as described herein.

FIGS. 1A to 1G are diagrams illustrating cross-sectional views of a method of forming a bump electrode in accordance with example embodiments;

FIG. 2 is a flow chart illustrating a method of removing a photoresist pattern using a composition for removing photoresist in accordance with example embodiments;

FIGS. 3 to 6 are images showing the surface of wafers wherein a photoresist film is removed using compositions prepared in accordance with Examples 1 to 4, respectively; and

FIGS. 7 to 10 are images showing the surface of wafers wherein a photoresist film is removed using compositions prepared in accordance with Comparative Examples 1 to 3 and 10, respectively.

### DETAILED DESCRIPTION

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. The present invention may, however, be embodied in many alternative forms and should not be construed as limited to only the example embodiments set forth herein.

Accordingly, while the example embodiments are capable of various modifications and alternative forms, embodiments thereof are shown by way of example in the drawings and will herein be described in detail. It should be understood, however, that there is no intent to limit example embodiments to the particular forms disclosed, but on the contrary, the example embodiments are to cover all modifications, equivalents, and alternatives falling within the scope of the invention. Like reference numerals refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to the example embodiments described.

Example embodiments relate to a composition for removing a photoresist and a method of forming a bump electrode using the composition. Other example embodiments relate to a composition for more effectively removing a photoresist that may be used in a process for forming a bump electrode and a method of forming a bump electrode using the composition.

A composition for removing a photoresist according to example embodiments will now be described.

The composition may include an amine compound having a hydroxyl group, a polar organic solvent having a heteroatom, an alkylammonium hydroxide and water. The composition for removing photoresist may include about 22% wt. to about 46% wt. of the amine compound having a hydroxyl group, about 52% wt. to about 75% wt. of the polar organic solvent having a heteroatom, about 0.3% wt. to about 2% wt. of the alkylammonium hydroxide and a remainder of water.

The amine compound having a hydroxyl group may permeate through a photoresist film to detach (or remove) the photoresist film from an object. Examples of the amine compound that may be used for the composition may include hydroxylamine, monoethanolamine or the like. These may be used alone or in a mixture thereof.

When the composition includes less than about 22% wt. of the amine compound, then the photoresist film may not be sufficiently detached from the object, reducing the removability (or removal capability) of the composition. When the amount of the amine compound is greater than about 46% wt., then the photoresist detached from the object may not be readily dissolved in the composition. As such, photoresist residues may remain on the object. The composition according to example embodiments includes about 22% wt. to about 46% wt. of the amine compound, and preferably about 26% wt. to about 43% wt. of the amine compound.

The composition for removing a photoresist according example embodiments includes a polar organic solvent having a heteroatom. The polar organic solvent may dissolve the photoresist detached from the object to prevent (or reduce the amount of) photoresist residues from remaining on the object. Examples of the heteroatom in the polar organic solvent may include nitrogen, sulfur or the like. Examples of the polar organic solvent that may be used for the composition may include N-methyl-2-pyrrolidinone, dimethylacetamide, dimethyl sulfoxide or the like. These may be used alone or in a mixture thereof.

When the composition includes less than about 52% wt. of the polar organic solvent, then the photoresist detached from the object may not be sufficiently dissolved in the composition. As such, the photoresist residues may remain on the object. When the amount of the polar organic solvent is greater than about 75% wt., then the photoresist may not easily detach from the object so that the photoresist removability of the composition may be reduced and/or a polyimide film may be damaged by the composition. The composition includes about 52% wt. to about 75% wt. of the polar organic solvent. The composition may include about 55% wt. to about 72% wt. of the polar organic solvent.

The composition for removing photoresist according to example embodiments includes an alkylammonium hydroxide. The alkylammonium hydroxide may remove photoresist residues which are not removed by the amine compound and the polar organic solvent. The alkylammonium hydroxide may increase photoresist removability of the composition. The composition including the alkylammonium hydroxide may remove the photoresist at a relatively lower temperature within a relatively shorter time. An example of the alkylammonium hydroxide that may be used for the composition may include a tetraalkylammonium hydroxide having C₁-C₄ alkyl groups. Examples of the alkylammonium hydroxide may include tetramethylammonium hydroxide, tetraethylammonium hydroxide, tetrapropylammonium hydroxide, tetrabutylammonium hydroxide or the like. These may be used alone or in a combination thereof.

When the composition includes less than about 0.3% wt. of the alkylammonium hydroxide, photoresist residues may remain on the object. When the amount of the alkylammonium hydroxide is greater than about 2% wt., then the photoresist removability of the composition may not be further enhanced and a polyimide film may be damaged by the composition. The composition includes about 0.3% wt. to about 2% wt. of the alkylammonium hydroxide. The composition may include about 0.4% wt. to 1.5% wt. of the alkylammonium hydroxide.

The composition for removing photoresist according to example embodiments includes water with the amine compound, the polar organic solvent and the alkylammonium hydroxide. Examples of water that may be used for the composition may include pure water, ultra pure water, deionized water, distilled water, etc. The amount of water included in the composition may be adjusted in accordance with the concentration of the alkylammonium hydroxide and photoresist removabilities of the composition.

In accordance with example embodiments, the composition for removing photoresist may include monoethanolamine as the amine compound and N-methyl-2-pyrrolidinone as the polar organic solvent.

According to example embodiments, the composition for removing photoresist may prevent (or reduce) damage to a passivation layer formed using polyimide and/or may more effectively remove a novolac-based photoresist, used to form a bump electrode, at a lower temperature within a shorter time.

A method of forming a bump electrode in accordance with example embodiments will be described with reference to accompanying drawings.

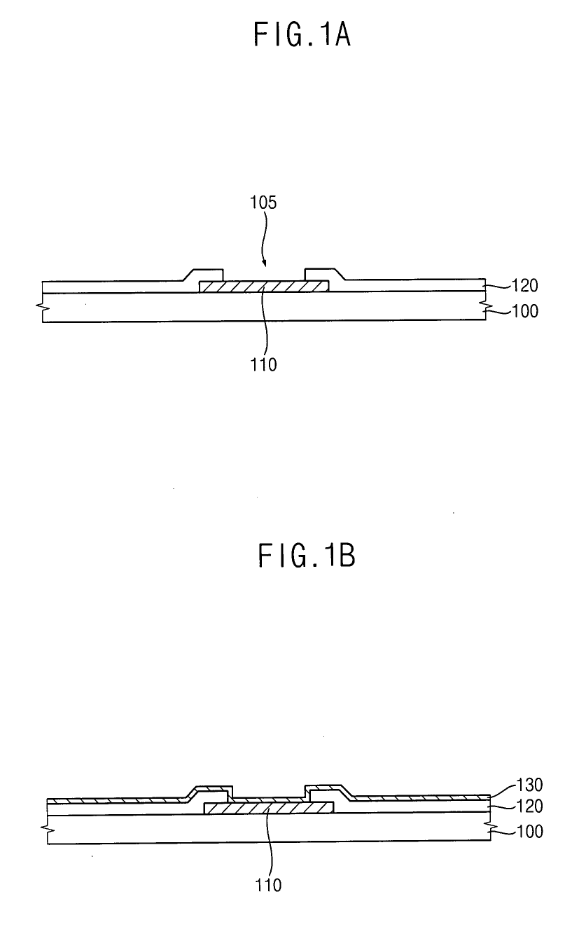

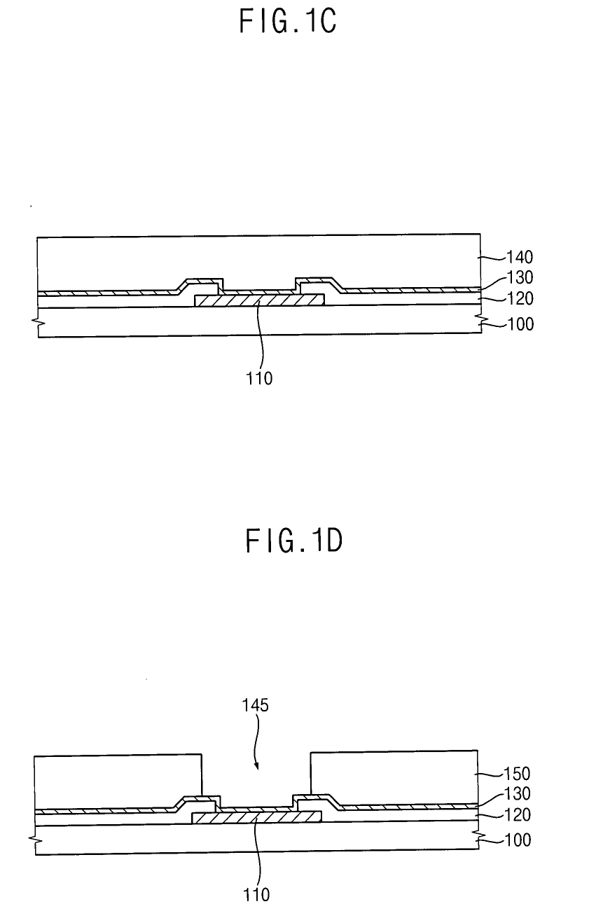

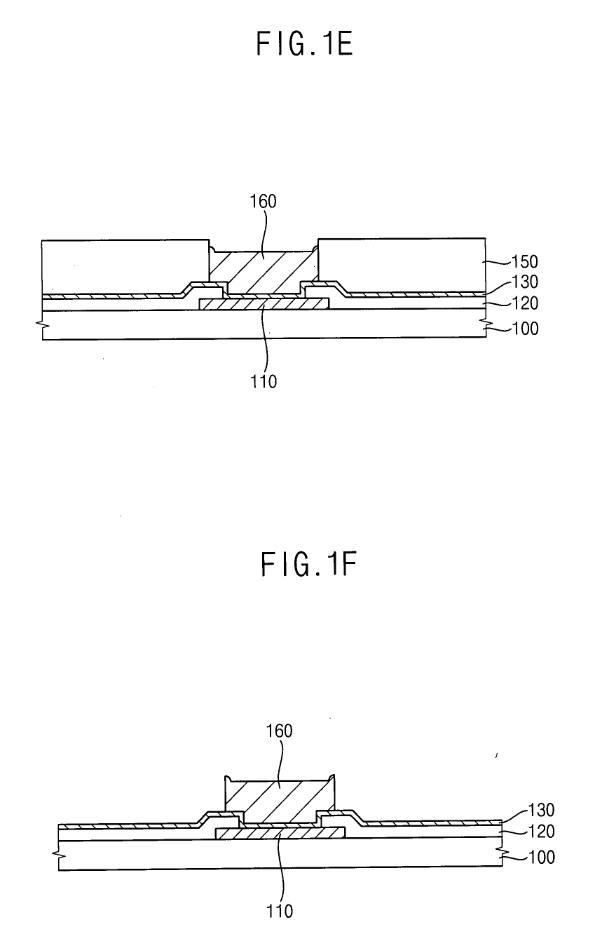

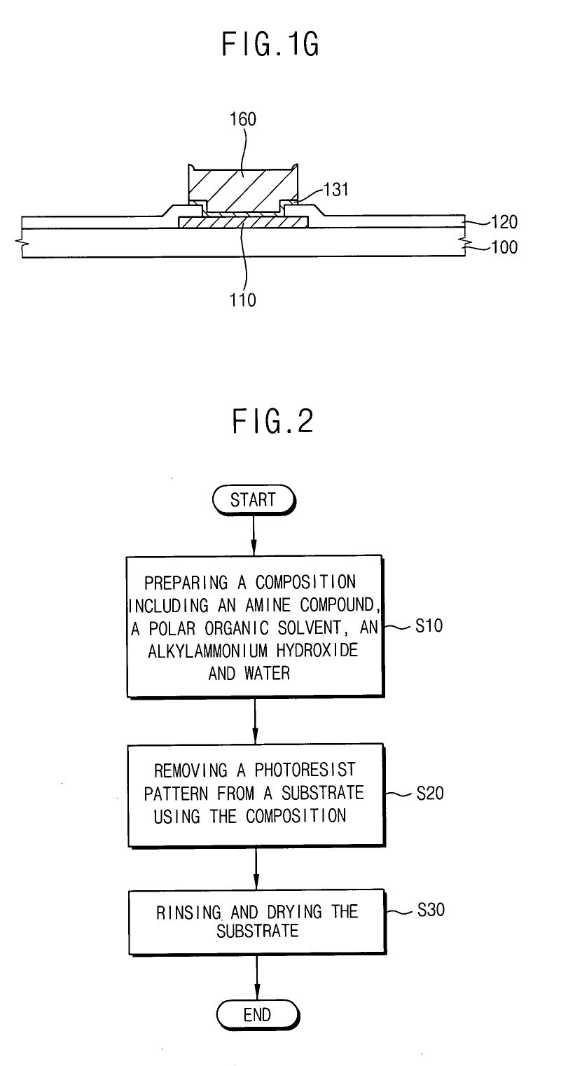

FIGS. 1A to 1G are diagrams illustrating cross-sectional views of a method of forming a bump electrode in accordance with example embodiments.

Referring to FIG. 1A, a conductive pattern 110 is formed on a substrate 100. The conductive pattern 110 may be formed using a metal (e.g., aluminum, tungsten or the like). A passivation layer 120 is formed on the substrate 100 over the conductive pattern 110 is formed. The passivation layer 120 may prevent (or reduce) damage to underlying structures (not shown) formed on the substrate 100 from during the formation of a bump electrode on the substrate 100. Examples of the underlying structures may include a gate structure, a capacitor, a wiring or the like. The passivation layer 120 may be formed using polyimide. The passivation layer 120 may be partially removed to form a first opening 105 that partially exposes the conductive pattern 110.

Referring to FIG. 1B, a seed layer 130 may be formed on the passivation layer 120 and the first opening 105. The seed layer 130 may be formed on a portion of the conductive pattern 110 exposed by the first opening 105, a sidewall of the first opening 105 and the passivation layer 120.

The seed layer 130 may be formed using a metal (e.g., titanium, nickel, palladium or the like). The seed layer 130 may be formed having a single-layered structure or a multi-layered structure. The seed layer 130 may be formed by a sputtering process. According to example embodiments, the seed layer 130 may be formed by depositing titanium through the sputtering process such that the seed layer 130 has a thickness of about 1,000 Å. In example embodiments, the seed layer 130 may be formed by depositing nickel through the sputtering process such that the seed layer 130 has a thickness of about 1,500 Å. In still other example embodiments, the seed layer 130 may be formed by depositing palladium through the sputtering process such that the seed layer 130 has a thickness of about 500 Å.

Referring to FIG. 1C, a photoresist film 140 is formed on the seed layer 130 by a coating process. The photoresist film 140 may be provided as a mold layer for forming a bump electrode through subsequent processes. The photoresist film 140 may be formed having a thickness sufficient (or desirable) for forming the bump electrode. For example, the photoresist film 140 may be formed having a thickness in a range of about 5 μm to about 30 μm. The photoresist film 140 may be formed using a photoresist that has a higher adhesive strength relative to an underlying layer and a higher plating solution resistance. An example of the photoresist having the above-mentioned characteristics may include a novolac-based photoresist.

Referring to FIG. 1D, the photoresist film 140 may be partially removed by an exposure process and a developing process to form a photoresist pattern 150 having a second opening 145 that exposes the first opening 105. The second opening 145 may have a dimension or a width substantially greater than or equal to the first opening 105. The seed layer 130 positioned on the conductive pattern 110 may be partially exposed through the second opening 145 and the first opening 105. When the second opening 145 has a width substantially greater than the first opening 105, then the second opening 145 may expose the first opening 105 and partially expose the seed layer 130 formed adjacent to the first opening 105.

Referring to FIG. 1E, a bump electrode 160 may be formed by an electroplating process 160 on the substrate 100 between the photoresist pattern 150 formed. The bump electrode 160 fills the first opening 105 and the second opening 145. The bump electrode 160 may be formed by depositing a metal (e.g., gold) through an electroplating process. The bump electrode 160 may be formed having a thickness substantially thinner or equal to the photoresist pattern 150. For example, the bump electrode 160 may be formed having a thickness in a range of about 11 μm to 20 μm.

Referring to FIG. 1F, the photoresist pattern 150 may be removed using the composition for removing photoresist according to example embodiments. A method of removing the photoresist pattern 150 using the composition will be fully described hereinafter.

FIG. 2 is a flow chart illustrating a method of removing a photoresist pattern using a composition for removing photoresist in accordance with example embodiments.

Referring to FIG. 2, the composition for removing photoresist may be prepared by mixing an amine compound having a hydroxyl group, a polar organic solvent having a heteroatom, an alkylammonium hydroxide and water (S10). Examples of the amine compound may include hydroxylamine, monoethanolamine or a combination thereof. Examples of the polar organic solvent may include N-methyl-2-pyrrolidinone, dimethylacetamide, dimethyl sulfoxide or the like. An example of the alkylammonium hydroxide may include a tetraalkylammonium hydroxide having C₁-C₄ alkyl groups. For example, the composition may be prepared by mixing about 22% wt. to about 46% wt. of the amine compound, about 52% wt. to about 75% wt. of the polar organic solvent, about 0.3% wt. to about 2% wt. of the alkylammonium hydroxide and a remainder of water. The composition for removing photoresist is previously described so further explanations will be omitted for the sake of brevity.

The photoresist pattern 150 may be removed from the substrate 100 by applying the composition to the substrate 100 (S20). The composition may be applied at a temperature of about 20° C. to about 80° C. The composition may be applied at a temperature of about 20° C. to 40° C. When the temperature of the composition is lower than about 20° C., then a removal of the photoresist pattern 150 may require a longer period of time. When the temperature of the composition is higher than about 80° C., the removal of the photoresist and/or changes in the concentration of the components may not be easily controlled. The passivation layer 120 formed using polyimide may be damaged by the higher temperature of the composition.

A conventional composition including monoethanolamine and dimethylacetamide removes a photoresist at a temperature of at least about 45° C., and preferably at a temperature of at least about 60° C. The composition according to example embodiments may have increased (or greater) photoresist removability. As such, the composition may more effectively remove the photoresist pattern 150 at a temperature lower than or equal to about 40° C. When the removal process of the photoresist pattern 150 is performed at a temperature lower than or equal to about 40° C., then a time required for applying the composition to the photoresist pattern 150 may be in a range of about 10 to 40 minutes. As such, the removal process of the photoresist pattern 150 may be performed with an enhanced (or increased) efficiency, and the passivation layer 120 formed using polyimide may be prevented (or reduced) reducing the possibility of generating a defect in a semiconductor device.

The substrate 100, from which the photoresist pattern 150 is removed, may be rinsed using deionized water and dried using nitrogen gas (S30).

Referring to FIG. 10, a portion of the seed layer 130 exposed by removing the photoresist pattern 150 may be removed to form a seed layer pattern 131 under the bump electrode 160. As such, the bump electrode 160, which may be formed on the seed layer pattern 131 and protrude from the substrate 100, is formed.

Example embodiments will be further described through the following examples and comparative examples. Example embodiments may, however, be embodied in many different forms and should not be construed as limited to examples set forth herein.

### Preparation of Compositions for Removing a Photoresist

### EXAMPLE 1

A composition for removing photoresist was prepared by mixing about 38% wt. of monoethanolamine (MEA), about 59% wt. of N-methyl-2-pyrrolidinone (NMP) and about 3% wt. of a tetramethylammonium hydroxide (TMAH) solution. The TMAH solution included about 25% wt. of TMAH and 75% wt. of water.

### EXAMPLES 2 TO 8

Compositions for removing a photoresist were prepared by substantiating the same processes as in Example 1 except for the type and amount of components. In the preparation of the compositions, (i) monoethanolamine (MEA) or hydroxylamine (HA) was used as an amine compound, (ii) N-methyl-2-pyrrolidinone (NMP), dimethylacetamide (DMAc) or dimethyl sulfoxide (DMSO) was used as a polar organic solvent and (iii) the 25% TMAH solution was used. The type and amount of components used for preparing the compositions are shown in Table 1.

### COMPARATIVE EXAMPLES 1 TO 10

Compositions for removing a photoresist were prepared by substantially the same processes as in Example 1 except for the type and amount of components. In the preparation of the compositions, (i) MEA or HA was used as an amine compound, (ii) NMP, DMAc or propylene glycol methyl ether acetate (PGMEA) was used as a polar organic solvent and (iii) the 25% TMAH solution was used. The type and amount of components used for preparing the compositions are shown in Table 1.

TABLE 1

| | AMINE | | POLAR | | |
|---|---|---|---|---|---|
| | COM- | | ORGANIC | | TMAH |
| | POUND | | SOLVENT | | SOLUTION |
| EXAMPLE | [% wt] | | [% wt] | | [% wt] |
| Example 1 | MEA | 38 | NMP | 59 | 3 |
| Example 2 | HA | 38 | NMP | 59 | 3 |
| Example 3 | HA | 38 | DMAc | 59 | 3 |
| Example 4 | HA | 38 | DMSO | 59 | 3 |
| Example 5 | MEA | 39 | NMP | 59 | 2 |
| Example 6 | MEA | 38 | NMP | 58 | 4 |
| Example 7 | MEA | 38 | NMP | 57 | 5 |
| Example 8 | MEA | 29 | NMP | 68 | 3 |
| Comparative Example 1 | MEA | 100 | — | | — |
| Comparative Example 2 | HA | 100 | — | | — |
| Comparative Example 3 | MEA | 23 | DMAc | 77 | — |
| Comparative Example 4 | MEA | 40 | NMP | 60 | — |
| Comparative Example 5 | MEA | 40 | NMP | 59 | 1 |
| Comparative Example 6 | MEA | 19 | NMP | 78 | 3 |
| Comparative Example 7 | MEA | 48.5 | NMP | 48.5 | 3 |
| Comparative Example 8 | MEA | 58 | NMP | 39 | 3 |
| Comparative Example 9 | MEA | 68 | NMP | 29 | 3 |
| Comparative Example 10 | HA | 38 | PGMEA | 59 | 3 |

### Evaluation of Photoresist Removabilities

The removal capability of the compositions prepared in Examples 1-8 and Comparative Examples 1-10 were evaluated.

To estimate the photoresist removal capability of the compositions, a photoresist film was formed on an electroplated wafer. Particularly, the photoresist film was formed using a novolac-based photoresist P-CS1500 (a trade name manufactured by TOK Co., Ltd., Japan). The photoresist film was formed having a thickness of about 20 μm. An exposure process and a developing process were performed on the photoresist film to form a photoresist pattern on the wafer. A bump electrode was formed by performing an electroplating process on a portion of the wafer exposed between the photoresist patterns. An O₂ treatment was performed on the wafer for several seconds.

In order to obtain several wafer pieces including the photoresist film and the bump electrode, the wafer on which the photoresist film and the bump electrode were formed was cut into several pieces of wafers having a dimension of about 3 cm×about 3 cm. Each wafer piece was immersed into the prepared composition for removing photoresist at a room temperature for about 20 minutes, thereby removing the photoresist film from the wafer piece. After the wafer piece was rinsed using deionized water for about five minutes, the wafer piece was dried using nitrogen gas. The wafer piece was observed using a microscope in order to determine whether the photoresist film was removed from the wafer.

TABLE 2

| EXAMPLE | REMOVED PHOTORESIST FILM |
|---|---|
| Example 1 | yes |
| Example 2 | yes |
| Example 3 | yes |
| Example 4 | yes |
| Example 5 | yes |
| Example 6 | yes |
| Example 7 | yes |
| Example 8 | yes |
| Comparative Example 1 | no |
| Comparative Example 2 | no |
| Comparative Example 3 | no |
| Comparative Example 4 | no |
| Comparative Example 5 | no |
| Comparative Example 6 | no |
| Comparative Example 7 | no |
| Comparative Example 8 | no |
| Comparative Example 9 | no |
| Comparative Example 10 | no |

As shown in Table 2, the compositions prepared in Examples 1 to 8 were completely (or substantially) removed the photoresist film and photoresist residues did not remain on the wafer. The compositions prepared in Comparative Examples 1 to 10 did not completely (or substantially) remove the photoresist film and photoresist residues remained on the wafer.

The compositions prepared in Comparative Examples 1 and 2 (including only the amine compound) did not cleanly remove the photoresist film. The compositions prepared in Comparative Examples 3 and 4 (including only the amine compound and the polar organic solvent) did not completely (or substantially) remove the photoresist film. The compositions in Examples 1 to 8 (including the amine compound, the polar organic solvent and the TMAH aqueous solution) more effectively removed the photoresist film without photoresist residues.

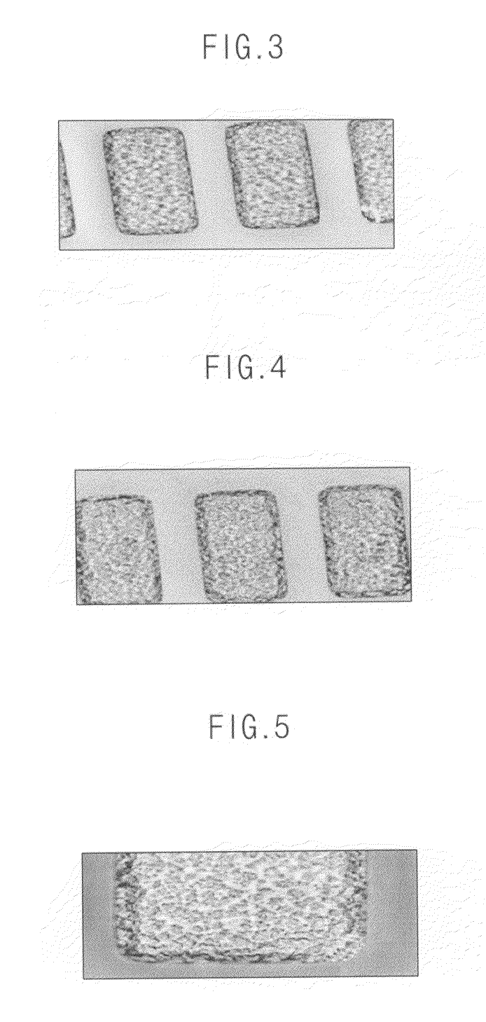

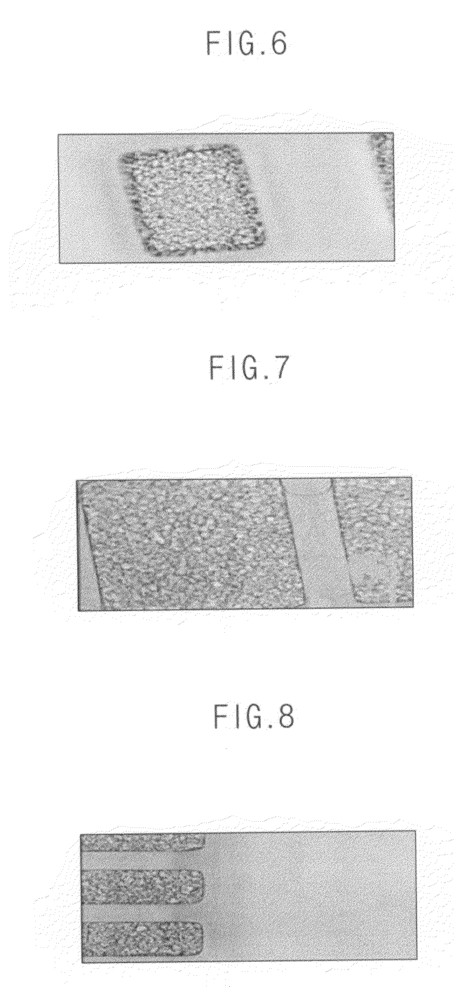

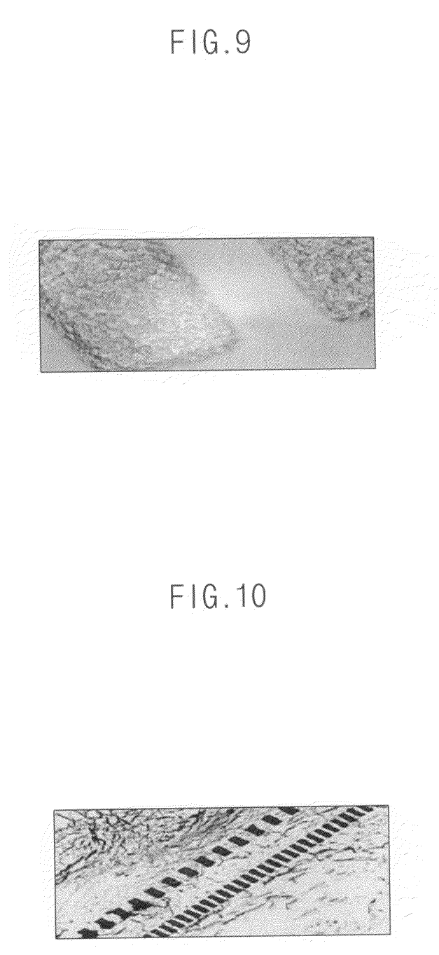

FIGS. 3 to 6 are images showing surfaces of wafers wherein a photoresist film is removed using compositions prepared in accordance with Examples 1 to 4, respectively. FIGS. 7 to 10 are images showing the surface of wafers wherein a photoresist film is removed using compositions prepared in accordance with Comparative Examples 1 to 3 and 10.

Referring to FIGS. 3 to 10, the compositions prepared in Examples 1 to 4 remove the photoresist film formed around the bump electrode and photoresist residues do not remain on the bump electrode and the wafer. The compositions prepared in Comparative Examples 1-3 and 10 do not completely (or substantively) remove the photoresist film and photoresist residues remaining on the wafers.

A larger amount of photoresist residues remain on the wafer cleaned using the composition prepared in Comparative Example 10, which includes propylene glycol methyl ether acetate (PGMEA) not having a nitrogen atom or a sulfur atom as the polar organic solvent. The compositions, which include the polar organic solvent having a heteroatom (e.g., a nitrogen atom or a sulfur atom) prepared in Examples 1 to 4, may completely (or substantially) remove the photoresist film without photoresist residues. The composition that includes the polar organic solvent having the heteroatom may have enhanced (or increased) dissolving ability with respect to photoresist and photoresist residues. The composition may more effectively remove photoresist.

The removal capabilities of the compositions according to an amount variation of the TMAH solution were evaluated by comparing the compositions prepared in Examples 1 and 5-7 to Comparative Examples 4 and 5. In the compositions, the weight ratio between the amine compound and the polar organic solvent was constantly maintained at about 40:60 and the amount of the 25% TMAH aqueous solution was changed from about 0% wt. to about 5% wt.

The compositions including the 25% TMAH aqueous solution in a range of about 0% wt. to about 1% wt. did not remove the photoresist film. The compositions including the 25% TMAH aqueous solution of at least about 2% wt. more effectively removed the photoresist film. Based on the amount of TMAH, the composition including TMAH less than 0.25% wt. had poorer photoresist removability. The composition including TMAH of at least about 0.50% wt. readily removed the photoresist film. The composition for removing photoresist may include the alkylammonium hydroxide of at least about 0.3% wt., and preferably at least about 0.4% wt.

The ability of the compositions to remove the photo resist according to a variation of the weight ratio between the amine compound and the polar organic solvent were evaluated by comparing the compositions prepared in Examples 1 and 8 to Comparative Examples 6-9. In the composition, the amount of the TMAH aqueous solution was constant and the weight ratio between MEA and NMP was adjusted into about 20:80, about 30:70, about 40:60, about 50:50, about 60:40 and about 70:30, respectively.

When the weight ratio between MEA and NMP was in a range of about 30:70 to about 40:60, then photoresist residues did not remain on the wafer and the photoresist film was completely (or substantially) removed. When the weight ratio between MEA and NMP was in a range of less than about 20:80 or greater than about 50:50, photoresist residues remained on the wafer and the photoresist film was not cleanly (or substantially) removed. The composition includes about 22% wt. to about 46% wt. of the amine compound. The composition may include about 26% wt. to about 43% wt. of the amine compound. The composition includes about 52% wt. to about 75% wt. of the polar organic solvent. The composition may include about 55% wt. to about 72% wt. of the polar organic solvent.

### Evaluation of Damages to a Polyimide Film

Damages to a polyimide film were evaluated for the compositions prepared in Examples 1-8 and Comparative Examples 1, 2, 3 and 10.

A polyimide film was formed, on a bare silicon wafer, having a thickness of about 3.28 μm. A developing process and an O₂ treatment were performed on the polyimide film formed on the wafer. The wafer including the polyimide film was cut into several pieces of wafers having a dimension of about 3 cm×about 3 cm. Each wafer piece was immersed into the prepared composition, removing the photoresist at a room temperature for about 20 minutes. After the wafer piece was rinsed using deionized water for about five minutes, the wafer piece was dried using nitrogen gas. The thickness of the remaining polyimide film was measured using Nanospec film thickness tester manufactured by KLA-Tencor Co., Ltd. in Japan.

TABLE 3

| | THICKNESS OF |
|---|---|
| | REMAINING POLYIMIDE FILM |
| EXAMPLE | [μm] |
| Example 1 | 3.27 |
| Example 2 | 3.20 |
| Example 3 | 3.23 |
| Example 4 | 3.26 |
| Example 5 | 3.27 |
| Example 6 | 3.26 |
| Example 7 | 3.18 |
| Example 8 | 3.25 |
| Comparative Example 1 | 0.0 |
| Comparative Example 2 | 0.0 |
| Comparative Example 3 | 3.14 |
| Comparative Example 10 | <0.01 |

As shown in Table 3, the compositions prepared according to Comparative Examples 1 and 2 (which include only the amine compound) substantially removed the polyimide film. The composition prepared in Comparative Example 10, which included the polar organic solvent not having a nitrogen atom or a sulfur atom, substantially dissolved the polyimide film. The compositions prepared in Examples 1 to 8 did not dissolve or damage the polyimide film. The composition including MEA as the amine compound and NMP as the polar organic solvent exhibited substantially no damage to the polyimide film.

According to example embodiments, the composition for removing photoresist may more effectively remove a novolac-based photoresist used for forming a bump electrode at a relatively lower temperature within a relatively shorter time. The composition may suppress (or reduce) damage to the polyimide film used for a passivation layer in a process for forming the bump electrode. The number of defects in a semiconductor device may be reduced or prevented.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A composition for removing photoresist, comprising:
about 22 percent by weight to about 46 percent by weight of an amine compound having a hydroxyl group;
about 52 percent by weight to about 75 percent by weight of a polar organic solvent having a heteroatom;
about 0.3 percent by weight to about 2 percent by weight of an alkylammonium hydroxide; and
a remainder of water.

2. The composition of claim 1, wherein the composition includes:
about 26 percent by weight to about 43 percent by weight of the amine compound;
about 55 percent by weight to about 72 percent by weight of the polar organic solvent;
about 0.4 percent by weight to about 1.5 percent by weight of the alkylammonium hydroxide; and
a remainder of water.

3. The composition of claim 1, wherein the composition includes about 26 percent by weight to about 43 percent by weight of the amine compound.

4. The composition of claim 1, wherein the composition includes about 55 percent by weight to about 72 percent by weight of the polar organic solvent.

5. The composition of claim 1, wherein the composition includes about 0.4 percent by weight to about 1.5 percent by weight of the alkylammonium hydroxide.

6. The composition of claim 1, wherein the amine compound includes at least one of hydroxylamine and monoethanolamine.

7. The composition of claim 1, wherein the polar organic solvent includes at least one selected from the group consisting of N-methyl-2-pyrrolidinone, dimethylacetamide and dimethyl sulfoxide.

8. The composition of claim 1, wherein the alkylammonium hydroxide includes a tetraalkylammonium hydroxide having C₁-C₄ alkyl groups.

9. The composition of claim 1, wherein the amine compound includes monoethanolamine, and the polar organic solvent includes N-methyl-2-pyrrolidinone.

10. A method of forming a bump electrode, comprising:
forming a conductive pattern on a substrate;
forming a passivation layer on the substrate, the passivation layer having a first opening that partially exposes the conductive pattern;
forming a photoresist pattern on the passivation layer, the photoresist pattern having a second opening that exposes the first opening;
forming a bump electrode that fills the first opening and the second opening; and
removing the photoresist pattern from the substrate using a composition including an amine compound having a hydroxyl group, a polar organic solvent having a heteroatom, an alkylammonium hydroxide and water.

11. The method of claim 10, wherein the composition includes:
about 22 percent by weight to about 46 percent by weight of the amine compound;
about 52 percent by weight to about 75 percent by weight of the polar organic solvent;
about 0.3 percent by weight to about 2 percent by weight of the alkylammonium hydroxide; and
a remainder of water.

12. The method of claim 10, wherein the photoresist pattern is formed using a novolac-based photoresist.

13. The method of claim 10, wherein the passivation layer is formed using polyimide.

14. The method of claim 10, further comprising applying the composition to the substrate at a temperature of about 20° C. to about 80° C.

15. The method of claim 14, further comprising applying the composition to the substrate at a temperature of about 20° C. to about 40° C.

16. The method of claim 10, further comprising forming a seed layer on a portion of the conductive pattern exposed by the first opening, a sidewall of the first opening and the passivation layer prior to forming the photoresist pattern.

17. The method of claim 16, wherein the bump electrode is formed by electroplating a conductive material.

18. The method of claim 16, further comprising removing a portion of the seed layer exposed by removing the photoresist pattern.
